(19) United States
(12) Patent Application Publication
(10) Pub. No.: US 2025/0107060 A1
(43) Pub. Date: Mar. 27, 2025

(54) METHOD FOR MANUFACTURING SEMICONDUCTOR DEVICE, SEMICONDUCTOR DEVICE, AND STATIC RANDOM ACCESS MEMORY CELL

(71) Applicant: HON HAI PRECISION INDUSTRY CO., LTD., New Taipei City (TW)

(72) Inventor: Chao-Wei KUO, Hsinchu City (TW)

(21) Appl. No.: 18/493,775

(22) Filed: Oct. 24, 2023

(30) Foreign Application Priority Data
Sep. 25, 2023 (TW) 112136661

(51) Int. Cl. H10B 10/00; H01L 29/08; H01L 29/78

(52) U.S. Cl. CPC H10B 10/12; H10D 30/601; H10D 62/151

(57) ABSTRACT

A semiconductor device includes a semiconductor substrate, a gate structure over the semiconductor substrate, first and second source/drain regions, and first and second local doped regions. The first and second source/drain regions are in the semiconductor substrate. The first local doped region is in the semiconductor substrate between the gate structure and the first source/drain region. The second local doped region is in the semiconductor substrate between the gate structure and the second source/drain region. The first and second local doped regions have a first conductive type, the first and second source/drain regions have a second conductive type different from the first conductive type. A doping concentration of the first local doped region is greater than a doping concentration of the second local doped region.

### CROSS-REFERENCE TO RELATED APPLICATION

This application claims priority to Taiwan Application Serial Number 112136661, filed Sep. 25, 2023, which is herein incorporated by reference in its entirety.

### BACKGROUND

### Field of Invention

The present disclosure relates to a method for manufacturing semiconductor device, a semiconductor device, and a static random access memory cell.

### Description of Related Art

The semiconductor integrated circuit (IC) industry has experienced exponential growth. Technological advances in IC materials and design have produced generations of ICs where each generation has smaller and more complex circuits than the previous generation. Static random access memory (SRAM) is often used in ICs. SRAM cells have advantage features of retaining data without the need for being refreshed. With the increase in the need for the speed of ICs, the reading speed and the writing speed become more important.

### SUMMARY

According to some embodiments of the present disclosure, a method for fabricating a semiconductor device, comprising: forming a gate structure over a semiconductor substrate, wherein the gate structure has opposite first and second sides; forming a first mask, wherein the first mask covers a second side of the gate structure and does not cover a first side of the gate structure; using the first mask, performing a first ion implantation process to form a first local doped region in the semiconductor substrate adjacent to the first side of the gate structure, wherein the first local doped region has a first conductive type; forming a second mask, wherein the second mask exposes the first and second sides of the gate structure; using the second mask, performing a second ion implantation process to form a second local doped region in the semiconductor substrate adjacent to the second side of the gate structure and increase a doping concentration of the first local doped region, wherein the second local doped region has the first conductive type; and forming a source/drain region respectively on the first and second sides of the gate structure in the semiconductor substrate after forming the second local doped region, wherein the source/drain region comprises a second conductive type different from the first conductive type.

According to some embodiments of the present disclosure, a semiconductor device includes a semiconductor substrate, a gate structure over the semiconductor substrate, first and second source/drain regions, and first and second local doped regions. The first and second source/drain regions are in the semiconductor substrate. The first local doped region is in the semiconductor substrate between the gate structure and the first source/drain region. The second local doped region is in the semiconductor substrate between the gate structure and the second source/drain region. The first and second local doped regions have a first conductive type, the first and second source/drain regions have a second conductive type different from the first conductive type. A doping concentration of the first local doped region is greater than a doping concentration of the second local doped region.

According to some embodiments of the present disclosure, a static random access memory (SRAM) cell includes a first pull-up transistor, a first pull-down transistor, a second pull-up transistor, a second pull-down transistor, a first pass-gate transistor, and a second pass-gate transistor. The first pull-up transistor and the first pull-down transistor are coupled with each other to form a first inverter. The second pull-up transistor and the second pull-down transistor are coupled with each other to form a second inverter, in which the first and second inverters are coupled with each other. The first pass-gate transistor is coupled among the first inverter, the second inverter, and a first bit line. The second pass-gate transistor is coupled among the first inverter, the second inverter, and a second bit line. Each of the first and second pass-gate transistors comprises a pass-gate gate structure, a first source/drain region, a second source/drain region, a first local doped region between the pass-gate gate structure and the first source/drain region, and a second local doped region between the pass-gate gate structure and the second source/drain region. The first and second local doped regions comprise a first conductive type, the first and second source/drain regions comprise a second conductive type different from the first conductive type, and a doping concentration of the first local doped region is greater than a doping concentration of the second local doped region.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic cross-sectional view of a semiconductor device in accordance with some embodiments of the present disclosure.

FIG. 2 is a graph of current versus voltage of a semiconductor device in accordance with some embodiments of the present disclosure.

FIG. 3 is a circuit diagram of a static random access memory (SRAM) cell in accordance with some embodiments of the present disclosure.

FIG. 4 is a graph of Read Static Noise Margin (RSNM) of memory cells in accordance with some embodiments of the present disclosure.

FIG. 5 is a graph of Write Static Noise Margin (WSNM) of memory cells in accordance with some embodiments of the present disclosure.

FIGS. 6A-10 illustrate schematic views of various stages in the manufacture of an integrated circuit including the SRAM cell of FIG. 3 in accordance with some embodiments of the present disclosure.

### DETAILED DESCRIPTION

The following disclosure provides many different embodiments, or examples, for implementing different features of the provided subject matter.

Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

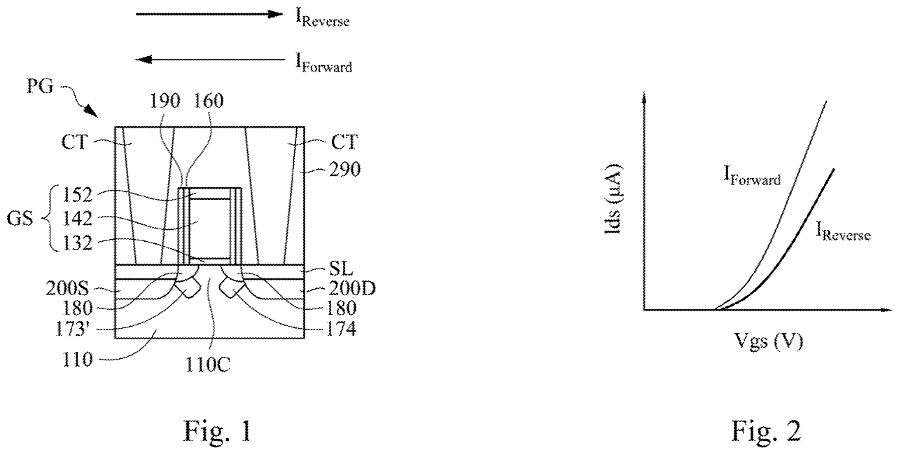

FIG. 1 is a schematic cross-sectional view of a semiconductor device PG in accordance with some embodiments of the present disclosure. In the context, the semiconductor device PG can be referred to as a pass-gate transistor, used in a static random access memory (SRAM) cell. The semiconductor device PG includes a semiconductor substrate 110, a gate structure GS, source/drain regions 200S and 200D, and local doped regions 173′ and 174. In some embodiments of the present disclosure, the semiconductor device PG is illustrated as a n-type transistor or a p-type transistor.

The gate structure GS is over a channel region 110C of the semiconductor substrate 110. The gate structure GS may include a gate dielectric 132, a gate electrode 142, and a hard mask 152. The gate dielectric 132 may include a suitable dielectric material, such as silicon dioxide. The gate electrode 142 may include a suitable conductive material, such as polysilicon. The hard mask 152 may include a suitable dielectric material, such as silicon nitride, silicon carbide, etc.

The source/drain regions 200S and 200D are disposed in the semiconductor substrate 110, and on opposite sides of the gate structure GS. For a n-type semiconductor device PG, the source/drain regions 200S and 200D are doped with n-type dopants, such as phosphorus (P), arsenic (As), tellurium (Te), etc., to have n-type conductivity. In various embodiments of the present disclosure, the doping concentrations of the source/drain regions 200S and 200D are substantially the same. In some embodiments herein, the source/drain region 200S may be referred to as the source region of the transistor, and the source/drain region 200D may be referred to as the drain region of the transistor. In other embodiments herein, the source/drain region 200S may be referred to as the drain region of the transistor, and the source/drain region 200D may be referred to as the source region of the transistor.

The local doped regions 173′ and 174 can also be called halo regions, which are counter-doped against the source/drain regions 200S and 200D. The local doped region 173′ is located in the semiconductor substrate 110 between the gate structure GS and the source/drain region 200S. Specifically, the local doped region 173′ is located between the channel region 110C and the source/drain region 200S. The local doped region 174 is located in the semiconductor substrate 110 between the gate structure GS and the source/drain region 200D. Specifically, the local doped region 174 is located between the channel region 110C and the source/drain region 200D. For the n-type semiconductor device PG, the local doped regions 173′ and 174 can be doped with p-type dopants, such as boron (B), aluminum (Al), gallium (Ga), etc., to have p-type conductivity. In various embodiments of the present disclosure, the doping concentration (e.g., p-type dopant concentration) of the local doped region 173′ is greater than the doping concentration (e.g., p-type dopant concentration) of the local doped region 174. The difference in doping concentrations can adjust the forward current I_{Forward} and the reverse current I_{Reverse} of the semiconductor device PG, wherein the forward current I_{Forward} flows from the source/drain region 200D to the source/drain region 200S, the reverse current I_{Reverse} flows from the source/drain region 200S to the source/drain region 200D.

In other embodiments, when the semiconductor device PG is a p-type transistor, the source/drain regions 200S and 200D may be doped with p-type dopants, the local doped regions 173′ and 174 may be doped with n-type dopants, and the doping concentration (e.g., n-type dopant concentration) of the local doped region 173′ is greater than the doping concentration (e.g., n-type dopant concentration) of the local doped region 174.

The semiconductor device PG also includes a lightly doped region 180, a metal silicide layer SL, gate spacers 160, 190, metal contacts CT, etc., and an interlayer dielectric layer 290 may surround the semiconductor device PG. These elements will be described in detail later.

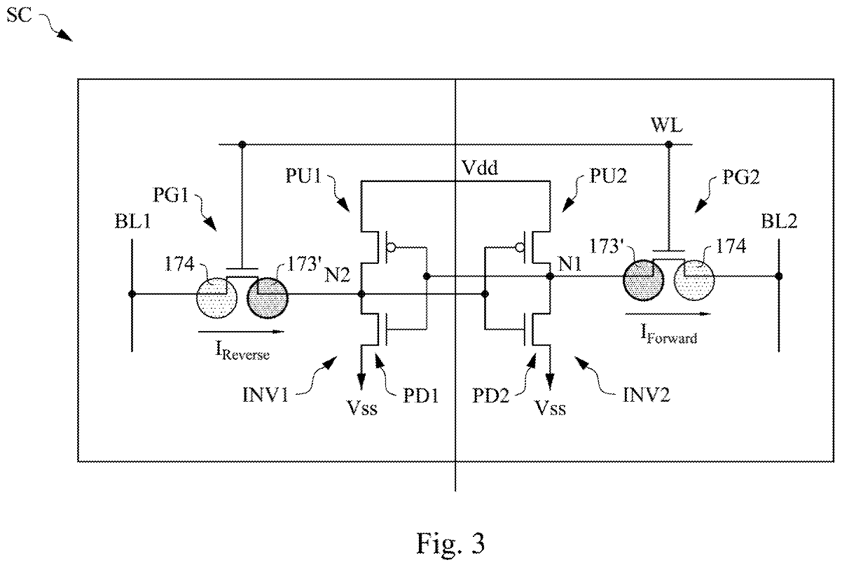

FIG. 2 is a graph of current versus voltage of a semiconductor device PG in accordance with some embodiments of the present disclosure. In FIG. 2, the horizontal axis is drain—source current (Ids), and the vertical axis is gate-source voltage (Vgs). By controlling the difference in doping concentrations between the local doped regions 173′ and 174, the forward current I_{Forward} and the reverse current I_{Reverse} of the semiconductor device PG can be adjusted such that the forward current I_{Forward} can be greater than the reverse current I_{Reverse}.

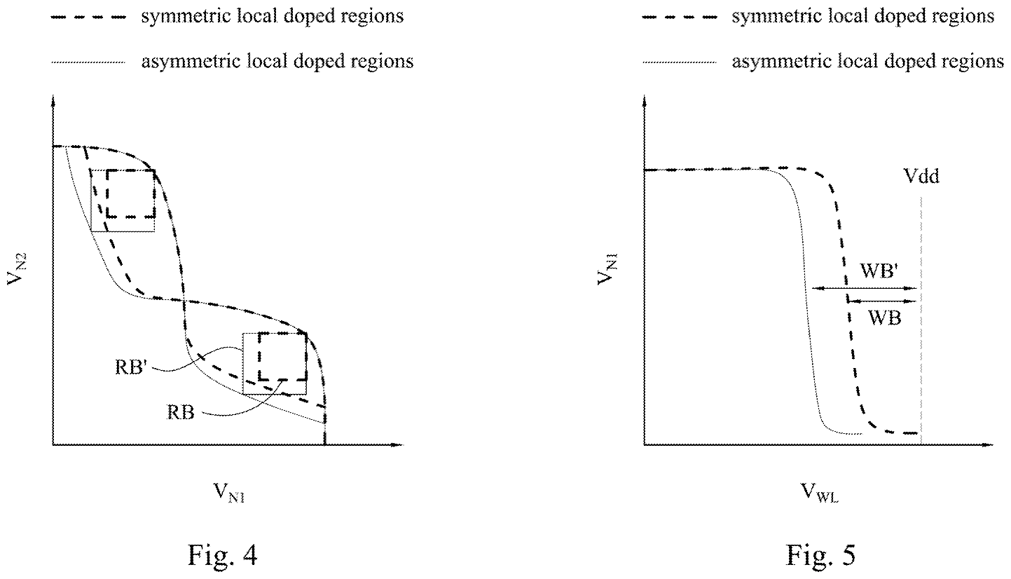

FIG. 3 is a circuit diagram of a static random access memory (SRAM) cell in accordance with some embodiments of the present disclosure. The static random access memory unit SC includes a pull-up transistor PU1, a pull-down transistor PD1, a pull-up transistor PU2, a pull-down transistor PD2, a pass-gate transistor PG1 and a pass-gate transistor PG2. FIG. 3 also shows a working voltage Vdd and a low voltage Vss. The low voltage Vss is, for example, ground terminal voltage or 0V.

The pull-up transistor PU1 and the pull-down transistor PD1 are coupled with each other to form a first inverter INV1. The pull-up transistor PU2 and the pull-down transistor PD2 are coupled with each other to form a second inverter INV2, in which the first inverter INV1 and the second inverter INV2 are coupled with each other. For example, an output terminal of the first inverter INV1 is connected to an input terminal of the second inverter INV2, labeled as a terminal N2; and an input terminal of the first inverter INV1 is connected to an output terminal of the second inverter INV2, labeled as a terminal N1.

The pass-gate transistor PG1 is coupled among the first inverter INV1, the second inverter INV2, and the bit line BL1. The pass-gate transistor PG2 is coupled between the first inverter INV1, the second inverter INV2, and the bit line BL2. Specifically, a source/drain terminal of the pass-gate transistor PG1 is connected to the output terminal of the first inverter INV1 and the input terminal of the second inverter INV2 (this contact point is marked as the terminal N2), and the other source/drain terminal of the pass-gate transistor PG1 is connected to the bit line BL1. Specifically, a source/drain terminal of the pass-gate transistor PG2 is connected to the input terminal of the first inverter INV1 and the out terminal of the second inverter INV2 (this contact point is marked as terminal N1), and the other source/drain terminal of the pass-gate transistor PG2 is connected to the bit line BL2. The control terminals (i.e., gate terminals) of the pass-gate transistors PG1 and PG2 are connected to a word line WL.

Herein, the structures of each of the pass-gate transistors PG1 and PG2 can be the same as that of the pass-gate transistor PG in FIG. 1, e.g., including the gate structure GS, the source/drain regions 200S and 200D, and the local doped regions 173′ and 174, in which the doping concentration of the local doped region 173′ is greater than the doping concentration of the local doped region 174. Through the configuration, different gate-source threshold voltages (Vt) can be generated at the two source/drain terminals of the pass-gate transistor PG1 and the pass-gate transistor PG2. As shown in the figure, on a side of the pass-gate transistor PG1 adjacent to the bit line BL1 and a side of the pass-gate transistor PG2 adjacent to the bit line BL2, a local doped region 174 with a lower concentration is provided to provide a relatively low gate-source threshold voltage; and on the other side of the pass gate transistor PG1 away from the bit line BL1 (i.e., the side adjacent to the first inverter INV1 and the second inverter INV2) and the other side of the pass gate transistor PG2 away from the bit line BL2 (i.e., the side adjacent to the first inverter INV1 and the second inverter INV2), a local doped region 173′ with a higher concentration is provided to provide a higher gate-to-source threshold voltage. In this way, the asymmetrical local doped regions results in an asymmetrical gate-source threshold voltages, thereby resulting in differences in the forward current I_{Forward} and the reverse current I_{Reverse}.

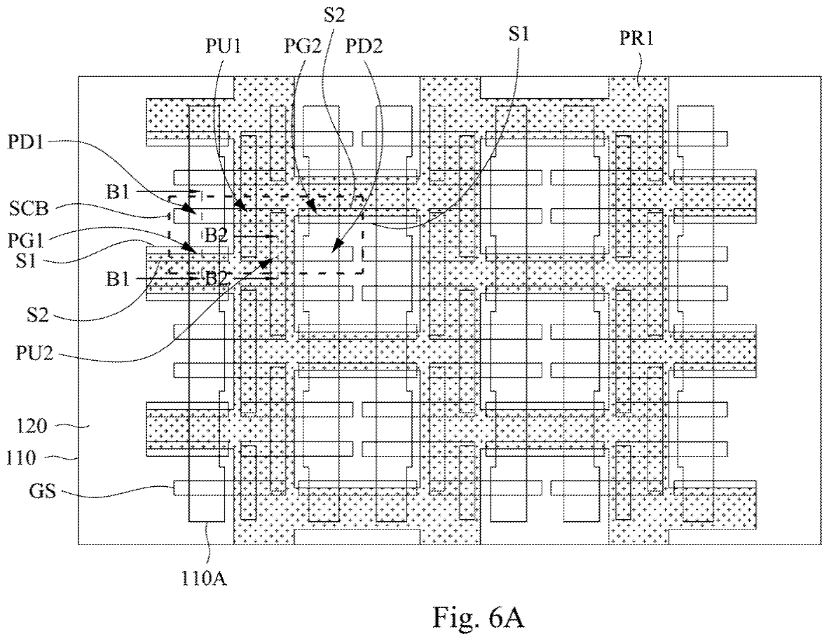

FIG. 4 is a graph of Read Static Noise Margin (RSNM) of memory cells SC in accordance with some embodiments of the present disclosure. In FIG. 4, the dotted line indicates a memory cell using pass-gate transistors with symmetric local doped regions, and the solid line indicates a memory cell using pass-gate transistors with asymmetric local doped regions. Reference is made to FIG. 4 and FIG. 3. In FIG. 4, the horizontal axis represents the voltage potential of the terminal N1 (named as V_{N1}), and the vertical axis represents the voltage potential of the terminal N2 (named as V_{N2}). Reference is made to FIG. 4 and FIG. 3. In the read operation, the potential of the word line WL become high to turn on the pass gate transistor PG1, and then the data in the device will be sensed on the bit line BL1. Read static noise margin is referred to as the maximum direct current (DC) noise voltage that can be tolerated under the read operation without changing the stored data. During the read operation, the bit line BL1 will be pre-charged to the operating voltage Vdd, and a voltage division is made at the terminals N1, N2, which store data as 1, which generate the problem of noise tolerance.

In various embodiments of the present disclosure, the read margin RB′ of the memory cell using the pass-gate transistors with asymmetric local doped regions is greater than the read margin RB of the memory cell using the pass-gate transistors with symmetric local doped regions. It can be known that the use of the asymmetric local doped regions can increase the read margin of the memory cell SC, which can further improve the noise tolerance.

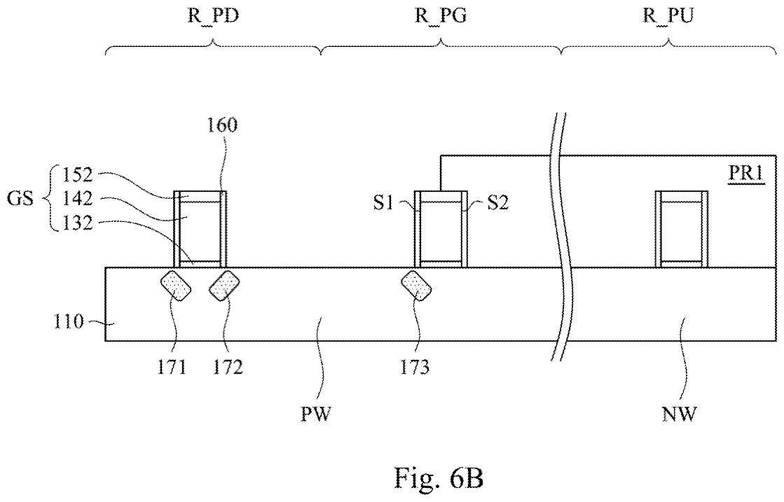

FIG. 5 is a graph of Write Static Noise Margin (WSNM) of memory cells in accordance with some embodiments of the present disclosure. In FIG. 5, the dotted line indicates a memory cell using pass-gate transistors with symmetric local doped regions, and the solid line indicates a memory cell using pass-gate transistors with asymmetric local doped regions. Reference is made to FIG. 5 and FIG. 3. In FIG. 5, the horizontal axis represents the voltage potential of the word line WL (denoted by V_{WL}), and the vertical axis represents the potential of the terminal N1 (denoted by V_{N1}). In the writing operation, the voltage level of the bit line BL2 is set to 0V, and the word line WL is changed to a high voltage potential to turn on the pass gate transistor PG2, then the voltage of the storage terminal N1 will turn (e.g., from the operating voltage Vdd) down to 0V.

In various embodiments of the present disclosure, the write margin WB′ of the memory cell using the pass-gate transistors with the asymmetric local doped regions is greater than the write margin WB of the memory cell using the pass-gate transistors with the symmetrical local doped regions. It can be known that the write margin of the memory cell SC can be increased by using the asymmetric local doped regions.

It can be observed from FIG. 4 and FIG. 5 that the use of asymmetric local doped regions can increase the read margin and write margin of the memory cell SC without sacrificing the chip area. When the circuit is connected to a low voltage, the margin of the memory cell can be significantly improved without relying on an increase in the area of the memory cell SC or design assistance.

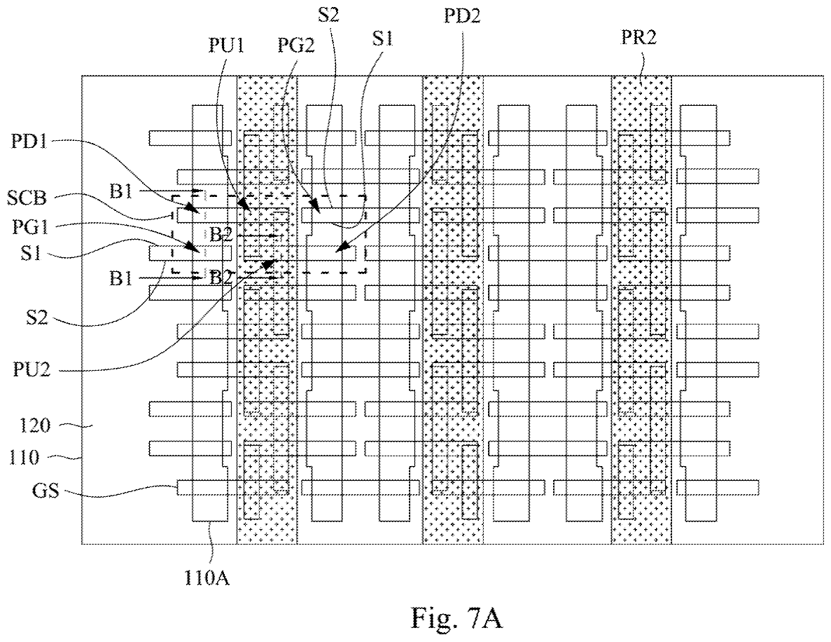

FIGS. 6A-10 illustrate schematic views of various stages in the manufacture of an integrated circuit including the SRAM cell of FIG. 3 in accordance with some embodiments of the present disclosure.

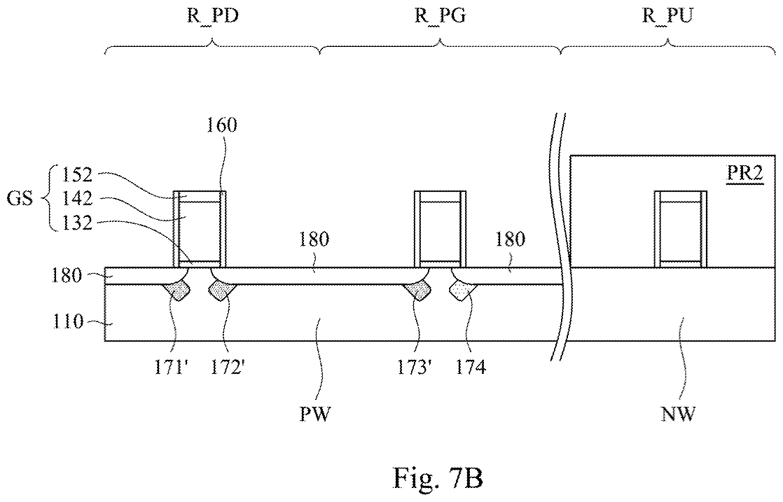

Plural memory cells SC (referring to FIG. 3) may be repeatedly arranged, and the range of one memory cell SC is defined herein by the memory cell boundary SCB. In some embodiments, FIGS. 6A, 7A can be regarded as schematic top views of manufacturing integrated circuits at various stages. FIGS. 6B, 7B, 8, 9, 10 are schematic cross-sectional views of manufacturing integrated circuits at various stages, including regions R_PD and R_PG taken along a line B1-B1 and a region R_PU taken along a line B2-B2 in FIGS. 6A, 7A.

In the schematic top view schematic of the context (e.g., FIGS. 6A, 7A), pull-down transistors PD1, PD2, pass gate transistors PG1, PG2 and pull up transistors PU1, PU2 are arranged in the memory cell boundary SCB. For the sake of illustration, in the schematic cross-sectional views of the context, the regions R_PD, R_PG, and R_PU respectively represent the regions where the pull-down transistors PD1, PD2, pass-gate transistors PG1, PG2, and pull-up transistors PU1, PU2 are located.

First of all, referring to FIGS. 6A, 6B, a semiconductor substrate 110 is provided. The semiconductor substrate 110 may include various elemental semiconductors, such as silicon or germanium; or compound semiconductors, such as silicon germanium. An isolation structure 120 is formed over the semiconductor substrate 110 to define plural active regions 110A.

The active regions 110A may have an appropriate width according to the transistors to be formed. For example, as shown in the figure, the width of the active regions 110A of the pull-down transistors PD1 and PD2 (referring to the region R_PD) is greater than the width of the active regions 110A of the pass-gate transistors PG1 and PG2 (referring to the region R_PG), and the width of the active regions 110A of the pass-gate transistors PG1 and PG2 (referring to the region R_PG) is greater than the width of the active regions 110A of the pull-up transistors PU1 and PU2 (referring to the region R_PU).

The active region 110A may be doped to have appropriate wells according to the conductivity type of the transistors to be formed. In some implementations, taking the SRAM cell SC in FIG. 3 as an example, the regions R_PD and R_PG for forming n-type transistors can be doped with p-type dopants to have p-type wells PW, and the region R_PU for forming p-type transistors may be doped with n-type dopants to have an n-type well NW. Among them, the p-type dopants can be boron (B), aluminum (Al), gallium (Ga), indium (In), and the n-type dopant can be phosphorus (P), Arsenic (As), antimony (Sb). For example, the doping concentrations of the wells NW and PW are about 1E15 cm⁻³ to about 1E18 cm⁻³.

In some embodiments, the semiconductor substrate 110 may provide planar active regions 110A for formation of planar field effect transistors. For example, the top surfaces of the active regions 110A may be substantially level with the top surface of the isolation structure 120. Alternatively, in some other embodiments, the semiconductor substrate 110 may be patterned to have active regions 110A of a specific shape, such as fins of a fin field-effect transistor (FinFET) being as the active regions 110A. For example, the top surface of the active regions 110A may be higher than the top surface of the isolation structure 120.

Next, a gate structure GS across the active region 110A (referred to FIG. 1) is formed.

Next, after forming the gate structure GS, a plurality of gate spacers 160 are formed on opposite sides S1 and S2 of the gate structure GS. The gate spacers 160 may include one or more layers. The gate spacers 160 may include one or more dielectric materials, such as silicon oxide, silicon nitride, and/or silicon oxynitride.

In the context, along the extending direction of the gate, the gate structure can be cut into plural independent and discontinuous gate structures, thereby achieving an integrated circuit. In the present embodiments, a gate cut process is performed on the polysilicon gate structure GS to form plural independent and discontinuous polysilicon gate structures GS. In other embodiments, the gate cut process can also be implemented in other process stages, and is not limited thereto.

Next, after forming the gate spacers 160, a mask PR1 is first formed over the semiconductor substrate 110. In some embodiments, the material of the mask PR1 may be an organic photoresist material, which is patterned by photolithography process, and the mask PR1 may also be referred to as a photomask. Alternatively, in other embodiments, the mask PR1 may include other mask materials, in which the mask PR1 is formed by forming a photoresist layer over the mask material through a photolithography process and patterning the mask material by an etching process. The mask PR1 covers the pull-up transistors PU1 and PU2 (referring to the region R_PU), and exposes the pull-down transistors PD1 and PD2 (referring to the region R_PD). The mask PR1 merely partially covers the pass gate transistors PG1 and PG2 (referring to the region R_PG). Specifically, for the pass-gate transistors PG1 and PG2 (referring to the region R_PG), the mask PR1 covers the side S2 of the gate structure GS, but does not cover the side S1 of the gate structure GS. Thereafter, with the mask PR1 in place, a first local ion implantation process is performed. For example, the doping dose of the first local ion implantation process is about 1E12 cm⁻² to about 1E14 cm⁻². The hard mask 152, the gate spacer 160, and the mask PR1 can be used as masks for the first local ion implantation process, thereby defining the regions being locally doped.

In the region R_PD, the first local ion implantation process forms first local doped regions 171 and 172 on the two sides S1 and S2 of the gate structure GS, respectively. In the region R_PG, the first local ion implantation process forms a first local doped region 173 in the semiconductor substrate 110 adjacent to the side S1 of the gate structure GS.

In some embodiments, the first local ion implantation process is a p-type doping process. In the region R_PD and the region R_PG for forming n-type transistors, the first local doped regions 171, 172, and 173 are doped with p-type dopants to have p-type conductivity. In some embodiments, the conductivity type of the first local doped regions 171, 172, 173 is the same as that of the well PW. After the formation of the first local doped region 173, the mask PR1 can be removed by a suitable removal (e. g., ashing) process.

Next, referring to FIGS. 7A and 7B, after removing the mask PR1, a mask PR2 is first formed on the semiconductor substrate 110. In some embodiments, the material of the mask PR2 may be an organic photoresist material, which is patterned by a photolithography process, and the mask PR2 may also be referred to as a photomask. Alternatively, in other implementations, the mask PR2 may include other mask materials, in which the mask PR2 is formed by forming a photoresist layer over the mask material through a photolithography process and patterning the mask material by an etching process. The mask PR2 covers the pull-up transistors PU1 and PU2 (referring to the region R_PU), and exposes the pull-down transistors PD1 and PD2 (referring to the region R_PD) and the pass-gate transistors PG1 and PG2 (referring to the region R_PG). Specifically, for the pass-gate transistors PG1 and PG2 (referring to region R_PG), the mask PR2 does not cover the sides S1 and S2 of the gate structure GS. Thereafter, with the mask PR2 in place, a second local ion implantation process is performed. For example, the doping dose of the second local ion implantation process is about 1E12 cm⁻² to about 1E14 cm⁻². In some embodiments, the doping dose of the second local ion implantation process is smaller than the doping dose of the first local ion implantation process, for example, the dopant dose of the first local ion implantation process is 2E13 cm⁻², the doping dose of the second local ion implantation process is 1E13 cm⁻². In other embodiments, the doping dose of the second local ion implantation process may be greater than that of the first local ion implantation process. The hard mask 152, the gate spacer 160, and the mask PR2 can be used as a mask for the second local ion implantation process, thereby defining the regions being locally doped.

In the region R_PD, the second local ion implantation process increases the doping concentrations of the first local doped regions 171 and 172 (referred to as local doped regions 171′ and 172′ hereinafter) on both sides S1 and S2 of the gate structure GS. In the region R_PG, the second local ion implantation process increases the doping concentration of the first local doped region 173 (referred to as a local doped region 173′ hereinafter) on the side S1 of the gate structure GS, and forms a second local doped region 174 in the semiconductor substrate 110 adjacent to the side S2 of the gate structure GS. The local doped regions 171′, 172′, and 173′ experience two local doping processes, and therefore have a higher concentration than the second local doped region 174. For example, the doping concentration of the well PW is in the range of about 1E15 cm⁻³ to about 1E18 cm⁻³, and the doping concentrations of the local doped regions 171′, 172′, 173′, and 174 are in the range of about 1E17 cm⁻³ to about 1E19 cm⁻³. The doping concentrations of the local doped region 171′, 172′, and 173′ are greater than that of the local doped region 174. In some embodiments, the doping concentrations of the local doped regions 171′, 172′, and 173′ may be substantially the same.

In some implementations, the second local ion implantation process is a p-type doping process. In the regions R_PD and R_PG for forming n-type transistors, the local doped regions 171′, 172′, and 173′ and the second local doped regions 174 are doped with p-type dopants to have p-type conductivity. In some embodiments, the conductivity types of the local doped regions 171′, 172′, and 173′ and the second local doped region 174 are the same as that of the well PW.

Next, referring to FIG. 7B, by using the same mask PR2, a lightly doped ion implantation process is performed to form source/drain lightly doped regions 180 over the semiconductor substrate 110 respectively on the sides S1 and S2 of the gate structure GS. The source/drain lightly doped regions 180 can also be referred to as source/drain extension regions (S/D extension regions). For example, in order to form n-type transistors, n-type dopants can be implanted into the semiconductor substrate 110 through a suitable ion implantation process to form the source/drain lightly doped regions 180. The hard mask 152, the gate spacers 160, and the mask PR2 can be used as a mask for ion implantation to define the regions of the source/drain lightly doped regions 180. For example, the doping concentrations of the source/drain lightly doped regions 180 are about 1E19 cm⁻³ to about 1E21 cm⁻³. In some embodiments, the doping concentrations of the lightly doped regions 180 of the source/drain regions may be substantially the same.

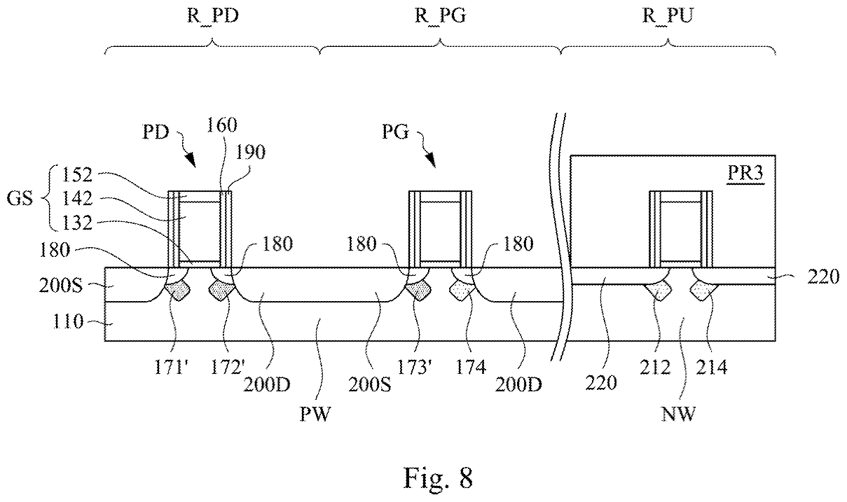

Next, referring to FIG. 8, after the formation of the source/drain lightly doped regions 180, the mask PR2 can be removed through an appropriate removal (e.g., ashing) process. Thereafter, through similar steps (e.g., photolithography process to form photomask and plural ion implantation processes), in the region R_PU for forming p-type transistors, n-type local doped regions 212 and 214 and p-type source/drain lightly doped regions 220 are formed. Among them, the local doped regions 212 and 214 can also be referred to as halo regions, and the source/drain lightly doped region 220 can also be called source/drain extension regions. The doping concentrations of the local doped regions 212 and 214 may be substantially the same. Thereafter, gate spacers 190 may be formed on both sides of the gate structure GS.

Next, a source/drain mask PR3 is formed by patterning the photoresist layer through a photolithography process. The material of the source/drain mask PR3 can be an organic photoresist material. Alternatively, in other embodiments, the source/drain mask PR3 may include other mask materials, in which the mask PR3 is formed by forming a photoresist layer over the mask material through a photolithography process and patterning the mask material by an etching process. The source/drain mask PR3 covers the region R_PU and exposes the regions R_PD and R_PG. Then, using the source/drain mask PR3, the source/drain regions 200S/200D can be formed in the semiconductor substrate 110 through a suitable ion implantation process. The ion implantation process can implant n-type dopants into the semiconductor substrate 110 to form source/drain regions 200S/200D of n-type transistors. The hard mask 152, the gate spacers 160, 190, and the source/drain mask PR3 can serve as masks for ion implantation to define the regions of the source/drain regions 200S/200D. The doping concentrations of the source/drain region 200S/200D are greater than that of the source/drain lightly doped regions 180. For example, the doping concentrations of the source/drain regions 200S/200D are in a range of about 5E19 cm⁻³ to about 5E21 cm⁻³. In some embodiments, the doping concentrations of the source/drain regions 200S/200D may be substantially the same.

In various embodiments of the present disclosure, for the same transistor, the source/drain regions 200S, 200D and the lightly doped regions 180 are doped with the same conductivity type (e.g., n-type), and the local doped regions 173′ and 174 and the well PW are doped with the same another conductivity type (e.g., p-type). Stated differently, the local doped regions 173′ and 174 and the well PW are counter-doped against the source/drain regions 200S, 200D and the lightly doped regions 180.

Accordingly, plural ion implantation processes are performed in the steps of FIG. 6A-8 to form n-type pull-down transistors PD and n-type channel gate transistors PG in the regions R_PD and R_PG. After the formation of the source/drain regions 200S/200D, the source/drain mask PR3 can be removed through a suitable removal (e.g., ashing) process.

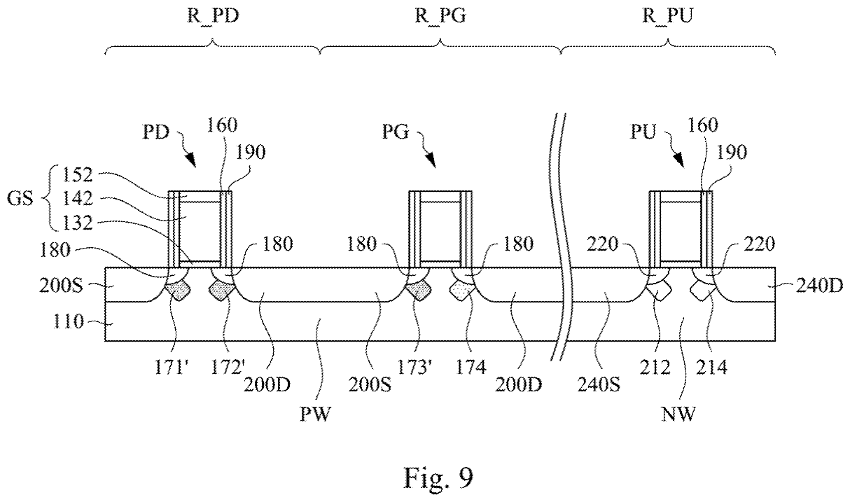

Next, referring to FIG. 9, in the region R_PU, p-type dopants can be implanted into the semiconductor substrate 110 through a p-type ion implantation process to form the source/drain regions 240S/240D of the p-type transistor. In some embodiments of the present disclosure, the source/drain region 240S may be referred to as the source region of the transistor, and the source/drain region 240D may be referred to as the drain region of the transistor. In other embodiments herein, the source/drain region 240S may be referred to as the drain region of the transistor, and the source/drain region 240D be referred to as the source region of the transistor.

In the process of forming the local doped regions 212 and 214, the source/drain lightly doped regions 220, and the source/drain regions 240S/240D of the p-type pull-up transistor PU, a suitable mask can be used to cover the regions R_PD and R_PG, and exposes the region R_PU, so as not to affect the features in the regions R_PD and R_PG. In the present embodiments, after forming the n-type pull-down transistors PD and the n-type pass-gate transistors PG, the p-type pull-up transistors PU are formed. In other embodiments, the order can be reversed, and the p-type pull-up transistors PU can be formed first, and then the n-type pull-down transistors PD and the n-type pass-gate transistors PG can be formed.

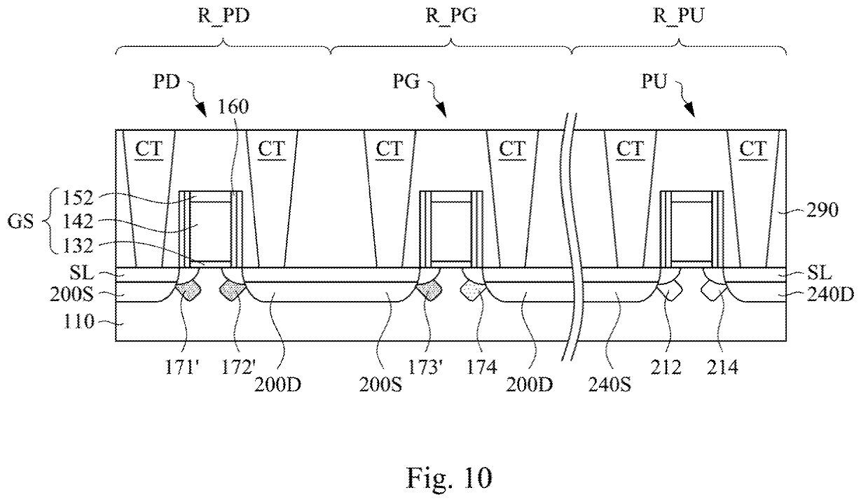

Next, referring to FIG. 10, an interlayer dielectric layer 290 is deposited on the gate structure GS. The interlayer dielectric layer 290 may comprise a suitable dielectric material, such as silicon dioxide. Thereafter, metal contacts CT are formed in the interlayer dielectric layer 290 to connect the source/drain regions 200S/200D or source/drain regions 240S/240D and the gate electrode 142 of each transistor. The metal contacts comprise a suitable conductive metal material, such as titanium, titanium nitride, tungsten, the like, or combinations thereof. Before forming the metal contact CT, metal silicide layers SL may be formed on the source/drain regions 200S/200D and the source/drain regions 240S/240D, thereby facilitating the electrical connection between the semiconductor doped region (such as the source/drain regions 200S/200D or source/drain regions 240S/240D) and the metal material (such as the metal contact CT).

In some embodiments of the present disclosure, a metal gate replacement process is performed after the process of FIG. 9 and before the process of FIG. 10, and the polysilicon gate structure GS (referring to FIG. 10) is replaced with a metal gate structure.

In some embodiments, a polishing process may be performed to remove the hard mask 152. The polishing process may include a chemical mechanical polish (CMP) process. Then, the gate electrode 142 and the gate dielectric 132 may be removed through a suitable etching process to leave a gate trench GT between the gate spacers 160. Thereafter, a high-k dielectric layer and a work function metal layer are conformally deposited into the gate trench GT, and filling the gate trench GT with a fill metal 430.

Based on the above discussions, it can be seen that the present disclosure provides advantages. It should be understood, however, that other embodiments may provide additional advantages, and not all advantages necessarily disclosed herein, and that no particular advantage is required for all embodiments. One of the advantages of the present disclosure is that asymmetric gate-source threshold voltages are created by using asymmetric local doping regions, thereby resulting in differences in forward current and reverse current. When the memory cell adopts the pass gate transistors with the asymmetric local doping regions, the read margin and the write margin can be increased.

What is claimed is:

1. A method for manufacturing a semiconductor device, comprising:
forming a gate structure over a semiconductor substrate, wherein the gate structure has opposite first and second sides;
forming a first mask, wherein the first mask covers a second side of the gate structure and does not cover a first side of the gate structure;
using the first mask, performing a first ion implantation process to form a first local doped region in the semiconductor substrate adjacent to the first side of the gate structure, wherein the first local doped region has a first conductive type;
forming a second mask, wherein the second mask exposes the first and second sides of the gate structure;
using the second mask, performing a second ion implantation process to form a second local doped region in the semiconductor substrate adjacent to the second side of the gate structure and increase a doping concentration of the first local doped region, wherein the second local doped region has the first conductive type; and
forming a source/drain region respectively on the first and second sides of the gate structure in the semiconductor substrate after forming the second local doped region, wherein the source/drain region comprises a second conductive type different from the first conductive type.

2. The method of claim 1, wherein the first conductive type is a p type, and the second conductive type is a n type.

3. The method of claim 1, further comprising:
using the second mask, performing a third ion implantation process to form a lightly doped region respectively on the first and second sides of the gate structure in the semiconductor substrate, wherein the lightly doped region comprises the second conductive type, and a doping concentration of the lightly doped region is lower than a doping concentration of the source/drain region.

4. The method of claim 1, wherein a doping dose of the first ion implantation process is greater than a doping dose of the second ion implantation process.

5. The method of claim 1, wherein a doping dose of the first ion implantation process is less than a doping dose of the second ion implantation process.

6. The method of claim 1, further comprising:
forming a well in the semiconductor substrate, wherein the well comprises the first conductive type, and forming the gate structure is performed such that the gate structure is over the well.

7. The method of claim 1, wherein forming the source/drain region comprises:
forming a third mask, wherein the second mask exposes the first and second sides of the gate structure; and
using the third mask, performing a third ion implantation process.

8. The method of claim 1, further comprising:
forming an isolation structure in the semiconductor substrate to define an active region, wherein forming the gate structure is performed such that the gate structure is over the active region, and the first ion implantation process and the second ion implantation process are performed such that the first and second local doped regions are in the active region.

9. A semiconductor device, comprising:
a semiconductor substrate; and
a gate structure over the semiconductor substrate; and
a first source/drain region and a second source/drain region in the semiconductor substrate;
a first local doped region in the semiconductor substrate between the gate structure and the first source/drain region; and
a second local doped region in the semiconductor substrate between the gate structure and the second source/drain region, wherein the first and second local doped regions comprise a first conductive type, the first and second source/drain regions comprise a second conductive type different from the first conductive type, and a doping concentration of the first local doped region is greater than a doping concentration of the second local doped region.

10. The semiconductor device of claim 9, wherein the first conductive type is a p type, and the second conductive type is a n type.

11. The semiconductor device of claim 9, wherein a doping concentration of the first source/drain region is substantially the same as a doping concentration of the second source/drain region.

12. The semiconductor device of claim 9, further comprising:
a well in the semiconductor substrate and below the gate structure, wherein the well comprises the first conductive type.

13. The semiconductor device of claim 9, further comprising:
a first lightly doped region in the semiconductor substrate and adjacent the first source/drain region; and
a second lightly doped region in the semiconductor substrate adjacent the second source/drain region, wherein the first and second lightly doped regions comprise the second conductive type and have a doping concentration less than a doping concentration of the first and second source/drain regions.

14. The semiconductor device of claim 9, further comprising:
an isolation structure in the semiconductor substrate and defining an active region, wherein the gate structure is over the active region, and the first and second local doped regions and the first and second source/drain regions are in the active region.

15. A static random access memory (SRAM) cell, comprising:
a first pull-up transistor and a first pull-down transistor, coupled with each other to form a first inverter;
a second pull-up transistor and a second pull-down transistor, coupled with each other to form a second inverter, wherein the first and second inverters are coupled with each other;
a first pass-gate transistor coupled among the first inverter, the second inverter, and a first bit line; and
a second pass-gate transistor coupled among the first inverter, the second inverter, and a second bit line, wherein each of the first and second pass-gate transistors comprises:
a pass-gate gate structure;
a first source/drain region and a second source/drain region;
a first local doped region between the pass-gate gate structure and the first source/drain region; and
a second local doped region between the pass-gate gate structure and the second source/drain region, wherein the first and second local doped regions comprise a first conductive type, the first and second source/drain regions comprise a second conductive type different from the first conductive type, and a doping concentration of the first local doped region is greater than a doping concentration of the second local doped region.

16. The SRAM cell of claim 15, wherein each of the first and second pull-down transistors comprises:
a pull-down gate structure;
a third source/drain region and a fourth source/drain region, wherein the third and fourth source/drain regions comprise the second conductive type;
a third local doped region between the pull-down gate structure and the third source/drain region; and
a fourth local doped region between the pull-down gate structure and the fourth source/drain region, wherein the third and fourth local doped regions comprise the first conductive type, and a doping concentration of the third local doped region is substantially the same as a doping concentration of the fourth local doped region.

17. The SRAM cell of claim 15, wherein the first conductive type is a p type, and the second conductive type is a n type.

18. The SRAM cell of claim 15, wherein a doping concentration of the first source/drain region is substantially the same as a doping concentration of the second source/drain region.

19. The SRAM cell of claim 15, wherein the doping concentration of the first local doped region and the doping concentration of the second local doped region are in a range of 1E17 cm⁻³ to 1E19 cm⁻³.

20. The SRAM cell of claim 15, wherein doping concentrations of the first source/drain region and the second source/drain region are in a range of 5E19 cm⁻³ to 5E21 cm⁻³.
